(19) United States
(12) Patent Application Publication
(10) Pub. No.: US 2019/0366858 A1
(43) Pub. Date: Dec. 5, 2019

(54) INDUCTION CHARGING DEVICE

(71) Applicant: Mahle International GmbH, Stuttgart (DE)

(72) Inventors: Tobias Franz, Brandenburg (DE); Christopher Laemmle, Stuttgart (DE); Timo Laemmle, 71394 (DE)

(21) Appl. No.: 16/425,202

(22) Filed: May 29, 2019

(30) Foreign Application Priority Data
May 30, 2018 (DE) 102018208628.1

(51) Int. Cl. B60L 53/122; H01F 38/14; H02J 50/10; H02J 7/02; H05K 7/20; H02J 7/00

(52) U.S. Cl. CPC B60L 53/122; H01F 38/14; H02J 50/10; H05B 2203/02; H05K 7/20945; H02J 7/0042; H02J 7/025

(57) ABSTRACT

An induction charging device for a partially or fully electrically operated motor vehicle may include a flat temperature control arrangement, a flat charging arrangement, and a heater. The temperature control arrangement may include at least one channel through which a cooling fluid is flowable. The charging arrangement may include at least one charging coil inductively couplable to an external primary coil during a charging process such that a battery of a vehicle is chargeable. The charging arrangement may be coupled to the temperature control arrangement to transfer heat such that a waste heat of the at least one charging coil during the charging process is transferable to the cooling fluid. The heater may be coupled to the temperature control arrangement to transfer heat such that a waste heat of the heater is transferable to the cooling fluid during the charging process and outside of the charging process.

### CROSS-REFERENCE TO RELATED APPLICATIONS

This application claims priority to German Patent Application No. DE 10 2018 208 628.1, filed on May 30, 2018, the content of which is hereby incorporated by reference in its entirety.

### TECHNICAL FIELD

The invention relates to an induction charging device for a partially or fully electrically operated motor vehicle.

### BACKGROUND

Induction charging devices are already known from the prior art and are used for the contact-free charging of a battery in a motor vehicle. An external primary coil is thereby inductively coupled to a secondary coil in the motor vehicle. An alternating current, which generates an electromagnetic alternating field around the primary coil, flows through the primary coil. In the secondary coil, the electromagnetic alternating field induces an alternating current, which is rectified by means of the power electronics and is supplied to the battery.

In response to the charging, a waste heat is generated in the primary coil and in the secondary coil due to energy losses. The waste heat generated in the secondary coil can in particular damage the power electronics in the induction charging device and has to be discharged to the outside. For this purpose, a cooling arrangement, through which a coolant can flow, can be arranged on the secondary coil. The cooling arrangement is thereby arranged on the secondary coil so as to transfer heat, so that the waste heat generated in the secondary coil is transferred to the cooling fluid.

The heat stored in the cooling fluid can then be dissipated into the environment or can be used to heat a lubricant in the motor vehicle, as is proposed, for example, in DE 10 2011 088 112 A1. During the charging, the waste heat can alternatively or additionally be used to preheat the interior and the battery or can be stored in a thermal energy storage. However, the amount of the waste heat generated in response to the charging is relatively low due to small currents and high voltages.

### SUMMARY

It is thus the object of the invention to specify an improved or at least alternative embodiment for an induction charging device of the generic type, in the case of which the heating process can be optimized in the motor vehicle and the waste heat can be used effectively.

This object is solved according to the invention by means of the subject matter of the independent claim(s). Advantageous embodiments are the subject matter of the dependent claim(s).

An induction charging device of the generic type is provided for a partially or fully electrically operated motor vehicle. The induction charging device has a flat temperature control arrangement comprising at least one channel, through which a cooling fluid can flow, and a flat charging arrangement comprising at least one charging coil—or a secondary coil, respectively. During a charging process, the charging coil can be inductively coupled to an external primary coil, and a battery of the motor vehicle can thus be charged. The charging arrangement is thereby coupled to the temperature control arrangement so as to transfer heat, so that the waste heat generated during the charging process in the charging coil can be transferred to the cooling fluid in the temperature control arrangement. According to the invention, the induction charging device has a heater, which is coupled to the temperature control arrangement so as to transfer heat, wherein the heat generated by the heater can be transferred to the cooling fluid in the temperature control arrangement during the charging process and outside of the charging process.

The temperature control arrangement thus represents a heat exchanger, in which the heat generated by the heater and the waste heat generated by the charging coil can be emitted to the cooling fluid. The temperature control arrangement thereby has at least one channel, which runs for example in a meandering fashion within the temperature control arrangement. Alternatively, the temperature control arrangement can have a plurality of channels, which are arranged next to one another and which are fluidically connected to a distributor pipe on the one hand and to a manifold on the other hand. Alternatively, the temperature control arrangement can be a housing, through which the cooling fluid can flow, wherein an interior of the housing forms the only channel of the temperature control arrangement. The temperature control arrangement is flat and the charging arrangement and the heater abut on the temperature control arrangement so as to transfer heat. The charging arrangement can thereby abut with a large surface—thus with 50% to 100% of a surface facing the temperature control arrangement—or with a small surface—thus with 10% to 50% of a surface facing the temperature control arrangement—on the temperature control arrangement so as to transfer heat. In the induction charging device according to the invention, the cooling fluid can be heated during the charging process by means of the waste heat of the charging coil and by means of the heat of the heater, and outside of the charging process by means of the heat of the heater. The induction charging device thus represents an additional heat source for the cooling fluid, during as well as outside of the charging process, and a cooling fluid main heater in the motor vehicle can be dimensioned to be smaller or can be replaced. The cooling fluid main heater can further be designed for a conservation operation, and the peak demands of the heating power in the motor vehicle can be covered by the heater of the induction charging device.

The heater can, for example, be a PTC heater (PTC: positive temperature coefficient) or a ceramic heater or a thick film heating element. To be able to adjust the heating power of the heater, a voltage applied to the heater can be regulated by means of a regulating unit or by means of an upstream DC (DC: direct current) converter of the induction charging device. The battery can advantageously supply the voltage to the heater, so that the heater can be operated during as well as outside of the charging process, and the cooling fluid can be heated.

In the case of a further development of the induction charging device according to the invention, it can be provided that the charging arrangement is secured to a first coupling side of the temperature control arrangement, and the heater is secured to a second coupling side located opposite the first coupling side. The heater and the charging arrangement thus abut on both sides of the temperature control arrangement. It can alternatively be provided that the heater and the charging arrangement are secured to a first coupling side or to a second coupling side located opposite the first coupling side of the temperature control arrangement. It can alternatively further be provided that the heater is arranged in the channel of the temperature control arrangement so that the cooling fluid can flow around it. In the case of this embodiment of the induction charging device, the heat exchange between the cooling fluid and the heater is intensified and the cooling fluid can be heated quickly and efficiently. It can further be provided that the charging coil of the charging arrangement, a power electronics unit for rectifying a current generated by the charging coil, a compensation unit for compensating a reactive power in the charging arrangement, a shielding arrangement for shielding electromagnetic interference fields and/or a field guiding arrangement for guiding electromagnetic fields to the charging arrangement can be arranged in the channel of the temperature control arrangement so that the cooling fluid can flow around them.

It can advantageously be provided that the heater has a plurality of individual heating elements, which are electrically interconnected to form the heater. The individual heating elements of the heather can thereby be arranged together or in each case to a first coupling side or to a second coupling side located opposite the first coupling side of the temperature control arrangement. The induction charging device can be embodied to be particularly space-saving in this way. The individual heating elements can alternative be secured in the channel of the temperature control arrangement so that the cooling fluid can flow around them. In the case of this embodiment of the induction charging device, the heat exchange between the cooling fluid and the heating elements is intensified and the cooling fluid can be heated quickly and efficiently. Regardless of the arrangement of the individual heating elements, they are coupled to the temperature control arrangement so as to transfer heat.

In the case of a further development of the induction charging device according to the invention it is provided that the induction charging device has a power electronics unit and/or a compensation unit for compensating a reactive power in the charging arrangement and/or a shielding arrangement for shielding electromagnetic interference fields and/or a field guiding arrangement for guiding electromagnetic fields to the charging arrangement. They can each be secured to a first coupling side or to a second coupling side located opposite the first coupling side of the temperature control arrangement or in the channel of the temperature control arrangement so that the cooling fluid can flow around them, and can be coupled to the temperature control arrangement so as to transfer heat. The waste heat generated in the mentioned components during the charging process can be emitted to the cooling fluid by means of the temperature control arrangement, and the mentioned components can thus be cooled. The power electronics unit and/or the compensation unit can thus have a plurality of electronic components, which generate a waste heat during the charging process. The shielding arrangement can have, for example, a metal plate—for example of aluminum—which, in the installed state of the induction charging device, shields the motor vehicle from electromagnetic interference fields of the charging arrangement during the charging process. The field guiding arrangement can be, for example, a magnet plate of a ferromagnetic material, which guides electromagnetic fields to the charging arrangement and thus increases the charging power of the charging arrangement. During the charging process, Eddy currents can occur in the metal plate and/or hysteresis losses can occur in the magnet plate, which generate a waste heat in the metal plate and/or in the magnet plate.

In the case of an advantageous embodiment of the temperature control arrangement, it is provided that the at least one channel of the temperature control arrangement changes, preferably decreases, its cross section in the area of a component, which is coupled so as to transfer heat. Alternatively or additionally, a turbulence insert can be arranged in the at least one channel of the temperature control arrangement in the area of a component, which is coupled so as to transfer heat. The heat-transferring component can thereby be the heater, the charging arrangement, the power electronics unit, the compensation unit, the shielding arrangement or the field guiding arrangement. The turbulence insert can be formed, for example, in a rib-shaped or wave-shaped or conical or step-shaped manner. Due to the change of the cross section and due to the turbulence insert, the heat transfer coefficient between the respective component and the cooling fluid can be adapted. The heating of the cooling fluid in the induction charging device or the cooling of the components, respectively, can be optimized in this advantageous manner.

It can advantageously be provided that the heater is secured to the temperature control arrangement in a positive manner or by means of a substance-to-substance bond or in a non-positive manner, and is coupled to the temperature control arrangement so as to transfer heat. The heater can, for example, be adhered to the temperature control arrangement. In particular a heat conducting silicon adhesive, a heat conducting thin film adhesive or a heat conducting two-component adhesive can be suitable for this purpose. The heater can alternatively be screwed or clamped to the temperature control arrangement. To couple the heater to the temperature control arrangement so as to transfer heat, a heat conducting heat conducting layer can be arranged between the heater and the temperature control arrangement. For example a heat conducting paste, a phase-changing film, a for example graphite-containing heat conducting path, a graphite film or a heat conductive adhesive can be suitable for this purpose. It is also conceivable that the heater and the temperature control arrangement are encapsulated in a housing. The heater can advantageously be electrically insulated from the temperature control arrangement by means of an insulating layer. A fiber-glass reinforced silicon film, a polyimide film, a heat conductive heat conducting adhesive, which is filled, for example, with glass beads, a heat conductive PSA adhesive strip (PSA: pressure sensitive adhesive), an insulating film comprising a phase-changing coating or a heat conducting path, for example, can be used for the insulating layer.

In the case of a further development of the induction charging device according to the invention, it can be provided that the temperature control arrangement can be fluidically coupled to a cooling fluid circuit. The heat generated by the heater and/or the waste heat generated by the charging coil can thus be transferred to the cooling fluid of the temperature control arrangement and via the cooling fluid in the cooling fluid circuit to further components during the charging process and outside of the charging process. The further components can be, for example, an interior of the motor vehicle or an oil container.

In summary, the cooling fluid in the induction charging device according to the invention can be heated during the charging process by means of the waste heat of the charging coil and by means of the heat of the heater, and outside of the charging process by means of the heat of the heater. The induction charging device can advantageously be used as an additional heat source for the cooling fluid during as well as outside of the charging process. A cooling fluid main heater can then be designed for a conservation operation, and the peak demands of the heating power in the motor vehicle can be covered by the heater of the induction charging device. The cooling fluid main heater in the motor vehicle can be dimensioned to be smaller or can be replaced, and the heating process as whole in the motor vehicle can be optimized.

Further important features and advantages of the invention follow from the subclaims, from the drawings, and from the corresponding figure description on the basis of the drawings.

It goes without saying that the above-mentioned features, and the features, which will be described below, cannot only be used in the respectively specified combination, but also in other combinations or alone, without leaving the scope of the present invention.

Preferred exemplary embodiments of the invention are illustrated in the drawings and will be described in more detail in the following description, whereby identical reference numerals refer to identical or similar or functionally identical components.

### BRIEF DESCRIPTION OF THE DRAWINGS

In the drawings, in each case schematically:

FIGS. 1 to 3 each show views of a differently embodied induction charging device according to the invention;

FIG. 4 shows a regulation scheme of a heater in the induction charging device according to the invention;

FIGS. 5 to 7 each show views of a heater, which is coupled differently to a temperature control arrangement;

FIG. 8 shows a sectional view of an induction charging device comprising a temperature control arrangement, which has a channel comprising a changing cross section.

### DETAILED DESCRIPTION

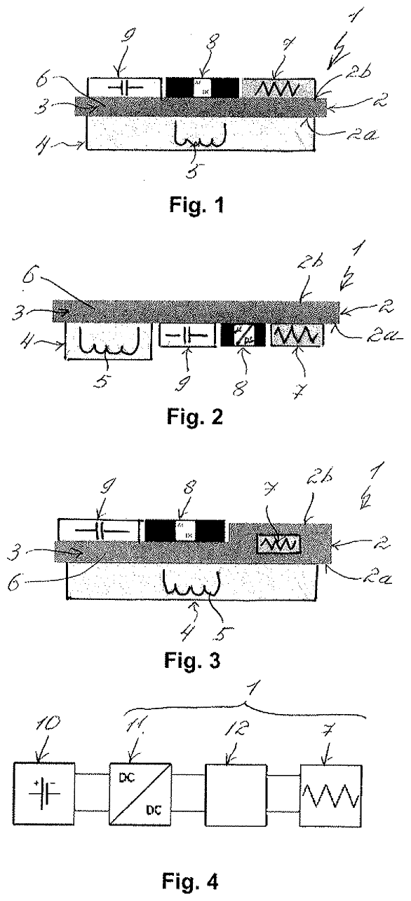

FIG. 1 to FIG. 3 show views of an induction charging device 1 according to the invention for a partially or fully electrically operated motor vehicle. The induction charging device 1 thereby has a flat temperature control arrangement 2 comprising a channel 3 and a flat charging arrangement 4 comprising a charging coil 5. The charging coil 5 can be inductively coupled to an external primary coil—not shown here—during a charging process, and a battery of the motor vehicle—not shown here—can thus be charged. The charging arrangement 4 is embodied so as to be flat and is secured across a large area to a first coupling side 2a of the temperature control arrangement 2 so as to transfer heat. A cooling fluid 6 can flow through the channel 3 of the temperature control arrangement 2, so that the waste heat generated in the charging coil 5 during a charging process can be transferred to the cooling fluid 6 in the temperature control arrangement 2. The induction charging device 1 also has a heater 7, which is coupled to the temperature control arrangement 2 so as to transfer heat. The heat generated by means of the heater 7 can thus be transferred to the cooling fluid 6 in the temperature control arrangement 2 during and outside of the charging process. The induction charging device 1 further has a power electronics unit 8 for rectifying a current generated during the charging process in the charging coil 5, and a compensation unit 9 for compensating a reactive power in the charging arrangement 4. The power electronics unit 8 and the compensation unit 9 are coupled to the temperature control arrangement 2 so as to transfer heat, so that waste heat generated therein during the charging process can be transferred to the cooling fluid 6.

The induction charging device 1 represents an additional heat source for the cooling fluid 6, which can heat the cooling fluid 6 during as well as outside of the charging process. The temperature control arrangement 2 can be fluidically coupled to a cooling fluid circuit, so that the heat absorbed by the cooling fluid 6 can be transported to further components during the charging process and outside of the charging process. The further components can be, for example, an interior, a heat storage, a battery or an oil container of the motor vehicle. The peak demands of the heating power in the motor vehicle can then be covered by the heater 7 of the induction charging device 1, and a cooling fluid main heater can be designed for a conservation operation and can thus be dimensioned to be smaller or can be replaced.

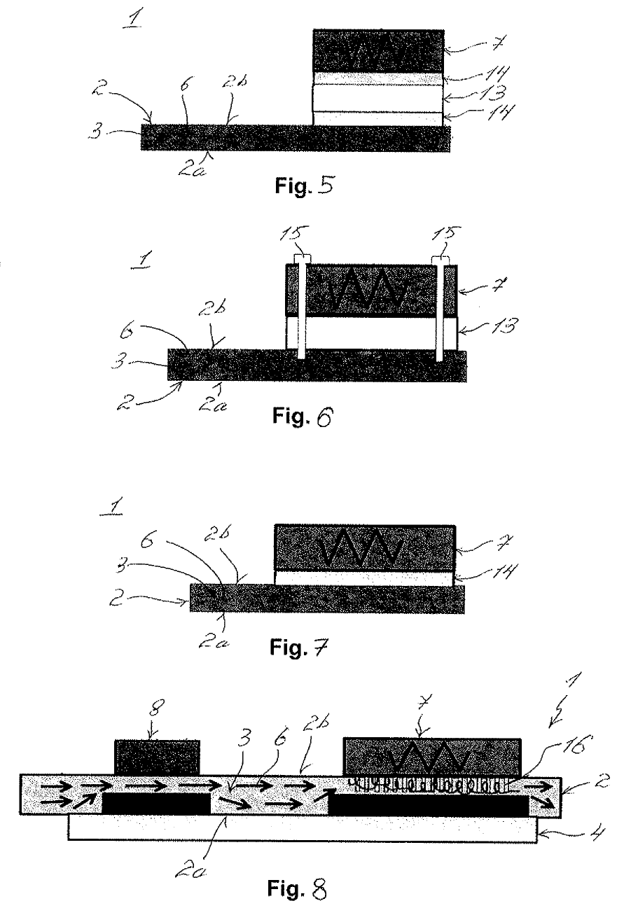

In FIG. 1 to FIG. 3, the charging arrangement 4 is secured to the first coupling side 2a of the temperature control arrangement by means of the charging coil 5. In FIG. 1, the heater 7, the power electronics unit 8, and the compensation unit 9 are secured to a second coupling side 2b, which is located opposite the first coupling side 2a, of the temperature control arrangement 2. In FIG. 2, the heater 7, the power electronics unit 8, and the compensation unit 9 are secured to the first coupling side 2a of the temperature control arrangement 2 next to the charging arrangement 4. In FIG. 3, the power electronics unit 8 and the compensation unit 9 are secured to the second coupling side 2b of the temperature control arrangement 2, and the heater 7 is arranged in the channel 3 of the temperature control arrangement 2, so that the cooling fluid 6 can flow around it on all sides. In the case of this embodiment of the induction charging device 1, the heat exchange between the cooling fluid 6 and the heater 7 is intensified and the cooling fluid 6 can be heated quickly and efficiently.

FIG. 4 shows a possible regulating scheme of the heater 7 in the induction charging device 1. A battery 10 thereby provides a voltage for the heater 7, which can be converted by means of an upstream DC converter 11 and can be further regulated by means of a regulating unit 12. The heater 7 can be operated during as well as outside of the charging process, and the cooling fluid 6 can accordingly be heated during as well as outside of the charging process. The heating power of the heater 7 can further be adapted to the current heating demand in the motor vehicle. The regulating schema of the heater 7 shown here is optional. The heater 7 can also be connected directly to the battery 10.

FIG. 5 to FIG. 7 show views of the heater 7, which is coupled to the temperature control arrangement 2 in a different way so as to transfer heat. In FIG. 5, the induction charging device 1 has a heat conducting insulating layer 13, which is arranged between the heater 7 and the second coupling side 2b of the temperature control arrangement 2. The heater 7, the insulating layer 13, and the temperature control arrangement 2 are thereby adhered to one another via heat conducting adhesive layers 14 and are coupled to one another so as to transfer heat. The adhesive layers 14 do not have to be electrically insulating thereby. When the adhesive layers 14 already have sufficient electrically insulating properties, the insulating layer 13 can be forgone. In FIG. 6, the heater 7 is screwed to the temperature control arrangement 2 via two screws 15. The heat conducting insulating layer 13 is thereby clamped between the heater 7 and the temperature control arrangement 2, and the heater 7 is thus coupled to the temperature control arrangement 2 so as to transfer heat. The screws 15 are advantageously electrically insulated from the heater 7 and/or from the temperature control arrangement 2 or consist of an electrically insulating material. If the heater 7 has an integrated electrical insulation, the insulating layer 13 can be replaced by an electrically non-insulating and heat conducting heat conducting layer. In FIG. 7, the heater 7 is connected to the temperature control arrangement 2 via the heat conducting adhesive layer 14. If the adhesive layer 14 does not have any electrically insulating properties, the heater 7 has to have an integrated electrical insulation. The adhesive layer 14 can alternatively be electrically insulating. Due to the thickness, the material, or additives, the properties of the adhesive layer 14 can be adapted, and the adhesive layer 14 can take over the electrically insulating function as well as the thermal connection of the heater 7 to the temperature control arrangement 2.

FIG. 8 shows a sectional view of the induction charging device 1. A possible flow direction of the cooling fluid 6 in the channel 3 is suggested by means of arrows. In this exemplary embodiment, the channel 3 of the temperature control arrangement 2 has a changing cross section in the area of the power electronics unit 8, which is coupled so as to transfer heat, and of the heater 7, which is coupled so as to transfer heat. In this exemplary embodiment, a turbulence insert 16 is further arranged in the channel 3 in the area of the heater 7, which is coupled so as to transfer heat. The heat transfer coefficient between the heater 7, the power electronics unit 8, and the cooling fluid 6 in the channel 3 can be adapted by means of the narrowing cross section and the turbulence insert 16, and the heat exchange can be intensified.

In summary, the cooling fluid 6 in the induction charging device 1 according to the invention can be heated during the charging process by means of the waste heat of the charging coil 5, of the power electronics unit 8, of the compensation unit 9, and by means of the heat of the heater 7, and outside of the charging process by means of the heat of the heater 7. The induction charging device 1 according to the invention can thus be used as an additional heat source for the cooling fluid 6, and a cooling fluid main heater can be dimensioned to be smaller or can be replaced.

1. An induction charging device for a partially or fully electrically operated motor vehicle, comprising:
a flat temperature control arrangement including at least one channel through which a cooling fluid is flowable;
a flat charging arrangement comprising including at least one charging coil;
the at least one charging coil inductively couplable to an external primary coil during a charging process such that a battery of a vehicle can thus be is chargeable;
the charging arrangement coupled to the temperature control arrangement to transfer heat such that a waste heat of the at least one charging coil during the charging process is transferable to the cooling fluid in the temperature control arrangement; and
a heater coupled to the temperature control arrangement to transfer heat;
wherein a waste heat by of the heater is transferable to the cooling fluid in the temperature control arrangement during the charging process and outside of the charging process.

2. The induction charging device according to claim 1, wherein one of:
the charging arrangement is secured to a first coupling side of the temperature control arrangement, and the heater is secured to a second coupling side of the temperature control arrangement disposed opposite the first coupling side;
the heater and the charging arrangement are secured to one of a first coupling side of the temperature control arrangement and a second coupling side of the temperature control arrangement disposed opposite the first coupling side; and
the heater is arranged in the at least one channel of the temperature control arrangement such that the cooling fluid is flowable around the heater.

3. The induction charging device according to claim 1, wherein:
the heater includes a plurality of individual heating elements which are electrically interconnected to define the heater, and
the plurality of individual heating elements are coupled to the temperature control arrangement to transfer heat, and are one of:
secured together;
each secured to a first coupling side of the temperature control arrangement;
each secured to a second coupling side of the temperature control arrangement disposed opposite the first coupling side; and
arranged in the at least one channel of the temperature control arrangement such that the cooling fluid is flowable around the plurality of individual heating elements.

4. The induction charging device according to claim 1, further comprising at least one of:
a power electronics unit configured to rectify a current provided by the at least one charging coil;
a compensation unit configured to compensate a reactive power in the charging arrangement;
a shielding arrangement for shielding electromagnetic interference fields; and a field guiding arrangement configured to guide electromagnetic fields to the charging arrangement;
wherein the at least one of the power electronics unit, the compensation unit, the shielding arrangement, and the field guiding arrangement is one of:
secured to a first coupling side or of the temperature control arrangement;
secured to a second coupling side of the temperature control arrangement disposed opposite the first coupling side; and
arranged in the at least one channel of the temperature control arrangement such that the cooling fluid is flowable around the at least one of the power electronics unit, the compensation unit, the shielding arrangement, and the field guiding arrangement; and
wherein the at least one of the power electronics unit, the compensation unit, the shielding arrangement, and the field guiding arrangement is coupled to the temperature control arrangement to transfer heat.

5. The induction charging device according to claim 1, further comprising a component coupled to the temperature control arrangement to transfer heat, wherein at least one of:
a cross section of the at least one channel changes in an area of the component;and
that a turbulence insert is arranged in the at least one channel in an area of the component.

6. The induction charging device according to claim 1, wherein the heater is secured to the temperature control arrangement one of i) in a positive manner, ii) via a substance-to-substance bond, and iii) in a non-positive manner.

7. The induction charging device according to claim 1, wherein the heater is electrically insulated from the temperature control arrangement via an insulating layer.

8. The induction charging device according to claim 1 wherein the heater is one of a PTC heater, a ceramic heater and a thick film heating element.

9. The induction charging device according to claim 1, wherein a voltage applied to the heater is regulatable via one of a regulating unit of the heater and an upstream DC converter.

10. The induction charging device according to claim 1, wherein the temperature control arrangement is fluidically couplable to a cooling fluid circuit such that at least one of the waste heat of the heater and the waste heat of the at least one charging coil transferred to the cooling fluid in the temperature control arrangement is transferrable, via the cooling fluid flowing in the cooling fluid circuit, to further components during the charging process and outside of the charging process.

11. The induction charging device according to claim 1, further comprising a power electronics unit configured to rectify a current provided by the at least one charging coil, the power electronics unit coupled to the temperature control arrangement to transfer heat, wherein the power electronics unit is one of:
secured to a first coupling side of the temperature control arrangement;
secured to a second coupling side of the temperature control arrangement disposed opposite the first coupling side; and
arranged in the at least one channel such that the cooling fluid is flowable around the power electronics unit.

12. The induction charging device according to claim 1, further comprising a compensation unit configured to compensate a reactive power in the charging arrangement, the compensation unit coupled to the temperature control arrangement to transfer heat, wherein the compensation unit is one of:
secured to a first coupling side of the temperature control arrangement;
secured to a second coupling side of the temperature control arrangement disposed opposite the first coupling side; and
arranged in the at least one channel such that the cooling fluid is flowable around the compensation unit.

13. The induction charging device according to claim 1, further comprising a shielding arrangement for shielding electromagnetic interference fields, the shielding arrangement coupled to the temperature control arrangement to transfer heat, wherein the shielding arrangement is one of:
secured to a first coupling side of the temperature control arrangement;
secured to a second coupling side of the temperature control arrangement disposed opposite the first coupling side; and
arranged in the at least one channel such that the cooling fluid is flowable around the shielding arrangement.

14. The induction charging device according to claim 1, further comprising a field guiding arrangement configured to guide electromagnetic fields to the charging arrangement, the field guiding arrangement coupled to the temperature control arrangement to transfer heat, wherein the field guiding arrangement is one of:
secured to a first coupling side of the temperature control arrangement;
secured to a second coupling side of the temperature control arrangement disposed opposite the first coupling side; and
arranged in the at least one channel such that the cooling fluid is flowable around the field guiding arrangement.

15. The induction charging device according to claim 1, further comprising a component coupled to the temperature control arrangement to transfer heat, wherein a cross section of the at least one channel decreases in an area of the component.

16. The induction charging device according to claim 1, further comprising:
a component coupled to the temperature control arrangement to transfer heat; and
a turbulence insert arranged in the at least one channel in an area of the component.

17. The induction charging device according to claim 1, wherein the heater includes a regulating unit configured to regulate a voltage applied to the heater.

18. The induction charging device according to claim 1, further comprising a DC converter arranged upstream of the heater configured to regulate a voltage applied to the heater.

19. The induction charging device according to claim 5, wherein the component is one of:
the heater;
the charging arrangement;
a power electronics unit configured to rectify a current provided by the at least one charging coil;
a compensation unit configured to compensate a reactive power in the charging arrangement;
a shielding arrangement for shielding electromagnetic interference fields; and
a field guiding arrangement configured to guide electromagnetic fields to the charging arrangement.

20. An induction charging device for an at least partially electrically operated motor vehicle, comprising:
a flat temperature control arrangement including at least one channel through which a cooling fluid is flowable;
a flat charging arrangement including at least one charging coil inductively couplable to an external primary coil such that a battery of a vehicle is chargeable during a charging process, the charging arrangement coupled to the temperature control arrangement such that a waste heat of the at least one charging coil is transferable to the cooling fluid during the charging process;
a heater defined by a plurality of electrically interconnected individual heating elements, the heater coupled to the temperature control arrangement such that a waste heat of the heater is transferable to the cooling fluid during the charging process and outside of the charging process; and
an insulating layer electrically insulating the heater from the temperature control arrangement.
